(19) United States
(12) Patent Application Publication
(10) Pub. No.: US 2026/0126400 A1
(43) Pub. Date: May 7, 2026

(54) OPTICAL INSPECTION OF WAFER BEVELS USING MULTIPLE LIGHT SOURCES

(71) Applicant: Applied Materials, Inc., Santa Clara, CA (US)

(72) Inventors: Zhi Wang, Redwood City, CA (US); Sidharth Bhatia, Santa Cruz, CA (US); Martin Seamons, San Jose, CA (US); Ganesh Balasubramanian, Fremont, CA (US); Ka Shun Wong, San Jose, CA (US)

(73) Assignee: Applied Materials, Inc., Santa Clara, CA (US)

(21) Appl. No.: 18/936,104

(22) Filed: Nov. 4, 2024

(51) Int. Cl. G01N 21/95; G01N 21/88; H01L 21/66; H01L 21/687

(52) U.S. Cl. CPC G01N 21/9503; G01N 21/8806; G01N 21/8851; H10P 72/7618; H10P 74/203

(57) ABSTRACT

Optical inspection of the surface of a substrate may take place in a factory interface where an aligner rotates the substrate to identify an alignment mark. While rotating, light may also be reflected off the surface of the substrate and captured by to identify defects or other variations on the substrate surface. However, the edge of the substrate often includes a bevel, and light directed at the edge of the substrate does not reflect off the bevel into the camera uniformly. Therefore, multiple light sources may be used simultaneously. For example, one light source may be directed perpendicularly at the edge of the bevel while another light source is directed at the bevel edge and configured such that light reflects off of the bevel into the camera. This provides an image with uniform lighting that can be more effectively used to identify defects on the edge of the substrate.

### TECHNICAL FIELD

This disclosure generally describes methods and systems for inspecting wafers manufactured in substrate processing systems. More specifically, this disclosure describes optical inspection techniques for use in identifying defects in substrates with bevel edges.

### BACKGROUND

Manufacturing of modern materials often involves various deposition techniques, such as chemical vapor deposition (CVD) or physical vapor deposition (PVD), in which atoms of one or more selected types are deposited on a substrate (wafer) held in low or high vacuum environments that are provided by vacuum deposition chambers. Manufacturing further includes various other techniques, such as etching, patterning, polishing, cleaning, stress mitigation, and/or the like. Materials manufactured in this manner include monocrystals, semiconductor films, fine coatings, and numerous other substances used in practical applications, e.g., electronic device manufacturing. Many of these applications rely on the quality of the materials grown in substrate processing systems, which in turn depends on the quality of wafers (e.g., bare wafers or wafers that underwent various preprocessing operations) used as substrates for device manufacturing. A wafer/substrate carrier may be docked to a load port of an equipment front end module (factory interface), where one or more substrates may be transferred to a load lock chamber or a process chamber (e.g., by a transfer robot). An environmentally-controlled atmosphere may be provided within and between the substrate carrier and the process chambers. To maintain isolation of inter-chamber environments and to increase product throughput, various robotic techniques of wafer manipulation and wafer inspection techniques may be used.

### SUMMARY

In some embodiments, a semiconductor manufacturing system may include an aligner configured to impart a rotational motion to a wafer and to identify, using the rotational motion of the wafer, a position of a reference feature of the wafer. The semiconductor manufacturing system may also include an optical inspection system configured to collect, during the rotational motion imparted by the aligner to the wafer, imaging data for a portion of the wafer. The optical inspection system may include a camera, a first light source positioned to direct light at a bevel of the wafer, and a second light source positioned to direct light perpendicularly at an edge of the wafer.

In some embodiments, an optical inspection system may include a pedestal configured to impart a rotational motion to a wafer; a camera configured to collect, during the rotational motion of the wafer, imaging data for at least a portion of the wafer; and a first light source positioned to direct light at a bevel of the wafer such that the light reflects off the bevel of the wafer into the camera.

In some embodiments, a method for inspecting a substrate. The method may include imparting a rotational motion to a wafer; directing light at a bevel of the wafer such that the light is reflected off of the bevel of the wafer into a camera; and collecting, using the camera, imaging data for the bevel of the wafer. The imaging data may be collected during the rotational motion imparted to the wafer. The method may also include identifying, using the imaging data, a presence of a defect on the bevel of the wafer.

In any embodiments, any and all of the following features may be implemented in any combination and without limitation. The first light source may be closer to the portion of the wafer than the second light source. The first light source may be at least 10% brighter than the second light source. A processing device may be programmed to identify, using the imaging data, a defect in the wafer. The aligner and the optical inspection system may be located in a factory interface coupled to at least one of a load lock chamber, a transfer chamber, or a processing chamber. The rotational motion of the wafer may occur with frequency between 30 rpm and 250 rpm. The imaging data may be collected for the portion of the wafer located within a distance d/10 from an edge of the wafer, where d is a diameter of the wafer. The system may include a deposition chamber and a transfer robot, where the transfer robot may be configured to move the wafer from the aligner to the deposition chamber after capturing the imaging data. The camera, the first light source, and the second light source may be positioned between about 5 mm and about 100 mm from the wafer. A second light source may be positioned to direct light perpendicularly at an edge of the wafer, where the second light source is separate and distinct from the first light source. The first light source may be positioned to direct light at a first portion of the bevel of the wafer; and the second light source may be positioned to direct light at a second portion of the bevel of the wafer. The first light source may be configured to emit light having a wavelength characterized by a blue color. The first light source may include a ring light around the camera. The first light source may include a dome light. The first light source may be positioned above a camera to capture the imaging data depicting a top portion of the bevel of the wafer. The defect(s) may include a chipping defect, a pitting defect, a film delamination defect, a bevel-edge defect, or a staining defect. A brightness of the light may be adjusted to adjust a quality of the imaging data.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

FIG. 1 illustrates a schematic view of an example processing system (e.g., a wafer processing system), according to some embodiments.

FIG. 2 illustrates a portion of an example optical inspection system for detection of defects in wafers rotated by an aligner, according to some embodiments.

FIG. 3 illustrates a diagram of a wafer, according to some embodiments.

FIG. 4A illustrates a portion of an optical inspection system using an overhead light to illuminate the bevel of the wafer, according to some embodiments.

FIG. 4B illustrates a portion of an optical inspection system using a ring light to illuminate the bevel of the wafer, according to some embodiments.

FIG. 4C illustrates a portion of an optical inspection system using a dome light to illuminate the bevel of the wafer, according to some embodiments.

FIG. 5 illustrates how the position or orientation of the optical inspection system itself may be changed to capture different zones on the wafer, according to some embodiments.

FIG. 6 illustrates an example architecture of a defect detection system, operating in accordance with some implementations of the present disclosure.

FIG. 7 illustrates a flowchart of a method for detecting defects around the perimeter of wafers, according to some embodiments.

FIG. 8 illustrates an exemplary computer system or controller in which various embodiments may be implemented.

### DETAILED DESCRIPTION

Optical inspection of the surface of a substrate may take place in a factory interface where an aligner rotates the substrate to identify an alignment mark. While rotating, light may also be reflected off the surface of the substrate and captured by to identify defects or other variations on the substrate surface. However, the edge of the substrate often includes a bevel, and light directed at the edge of the substrate does not reflect off the bevel into the camera uniformly. To overcome this technical challenge, multiple light sources may be used simultaneously. For example, one light source may be directed perpendicularly at the edge of the bevel while another light source may be directed at the bevel edge and configured such that light reflects off of the bevel into the camera. This provides an image with uniform lighting and contrast that can be more effectively used to identify defects on the edge of the substrate.

Wafers (substrates) that are delivered for processing in manufacturing chambers can include bare wafers (e.g., silicon wafers, quartz wafers, Gallium Arsenide wafers, corundum wafers), wafers that have been preprocessed (e.g., covered with one or more films, such as carbon films), or wafers that have already undergone one or more processing operations (e.g., deposition, patterning, etching, and so on). Operations with wafers (including bare wafer manufacturing) and transportation of wafers can leave or cause various defects in wafers, including but not limited to chipping near wafer edges, pitting (hole and depression formation), staining (e.g., water condensation or presence of extraneous materials), film peeling, non-uniformities of film beveling, and/or various other wafer imperfections. Undiscovered defects can result in expensive wasteful processing, sub-optimal and unusable manufacturing products, and even damage processing tools. To avoid this, wafers can be inspected using optical inspection systems and computer software that deploys defect detection algorithms. Such inspections, however, introduce an additional step into the manufacturing process, increase the total processing time, and adversely affect the manufacturing throughput.

Aspects and implementations of the present disclosure address these and other challenges of the wafer processing technology by enabling systems and techniques for fast defect identification. In some implementations, optical inspection of wafers can be performed while a wafer undergoes an alignment process. More specifically, wafers are typically delivered to manufacturing systems in wafer (substrate) carriers, such as front opening unified pods (FOUPs), which can hold multiple wafers at different stages of processing. A FOUP may be docked at the factory interface (front-end module), and a robot (e.g., located in a load lock chamber) may retrieve wafers from the FOUP through a sealable FOUP door for processing in one of the process chambers. Similarly, the robot may return fully or partially processed wafers into the FOUP. Orientations of wafers inside the FOUP are typically not controlled to a sufficient degree that would enable the robot to pick up an automatically aligned wafer in a way that would enable immediate wafer processing. Orientation of crystallographic axes (and/or directionality of various features that can be patterned on the wafer) of a wafer fetched from a FOUP can thus be arbitrary.

Correspondingly, an additional aligner station (device) is normally deployed to align wafers relative to some reference direction, e.g., a specific direction associated with a robot blade of the robot. The aligner can spin the wafer and locate, e.g., using various techniques of machine vision, a reference feature on the wafer that communicates to the robot (and/or other wafer manufacturing tools) orientation of the wafer. Such reference features include a notch that is cut into an edge of the wafer, a flat (cut-out) portion of the wafer's edge, or any other reference feature that breaks the circular symmetry of the wafer and is detectable by mechanical or optical techniques. The aligner device typically locates these reference features over several seconds of wafer's spinning on the aligner. A moving portion of the aligner (e.g., a chuck) typically rotates with frequency of about 50-200 rpm.

Optical inspection of a wafer may be performed while the wafer is rotated by the aligner. The defect inspection may be performed for the entire area of the wafer (e.g., via a line scan) or for an edge region of the wafer (e.g., within 10-15 mm from a wafer's edge). Edge regions often have a higher concentration of defects compared with the rest of the wafer's area and often determine whether the wafer is suitable for product processing. During optical inspection, a set of images of the wafer's edge (or the full area of the wafer) can be obtained by an optical inspection system and processed in real time by one or more trained defect detection models. Depending on the state of the wafer and the amount and types of identified defects, one or more decisions can be made, e.g., to use the wafer for further processing, to discard the wafer, to direct the wafer for remedial processing (e.g., removal of a deposited film and a deposition of a replacement film), and/or the like. As a result, sub-optimal wafers may be prevented from entering downstream processing at no additional time cost. The advantages of the disclosed implementations include, but are not limited to, efficient and low-cost optical real-time inspections that utilize existing hardware (e.g., aligner devices), increased quality of the processing yield, and prevention of damage of various processing tools by wafers that do not conform to processing specifications.

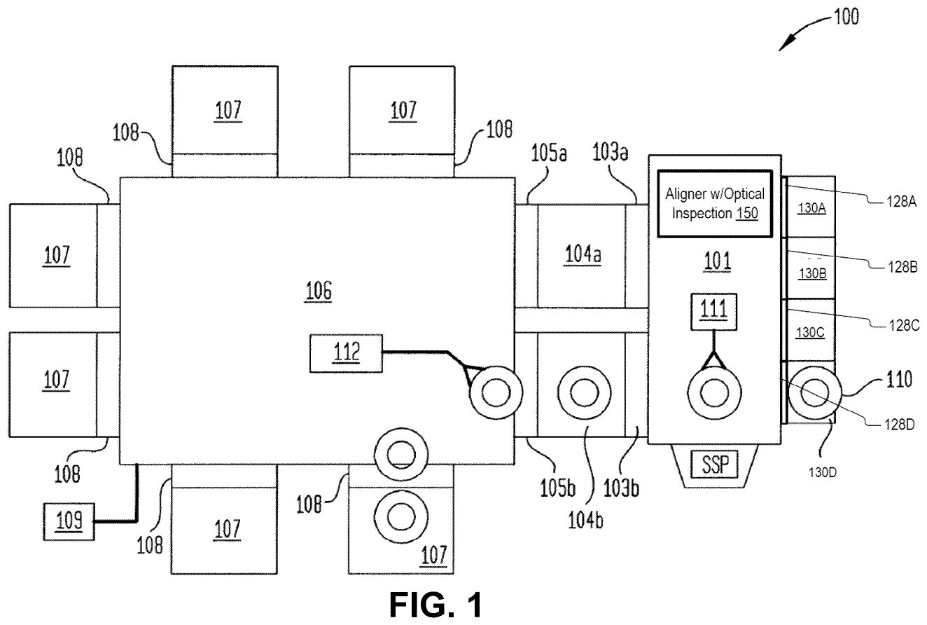

FIG. 1 illustrates a schematic view of an example semiconductor manufacturing system 100 (e.g., a wafer processing system), according to some embodiments. The processing system 100 may include a factory interface (FI) 101 and load ports 128 (e.g., load ports 128A-D). In some implementations, the load ports 128A-D are directly mounted to (e.g., sealed against) the FI 101. Enclosure systems 130 (e.g., cassette, FOUP, process kit enclosure system, or the like) are configured to removably couple (e.g., dock) to the load ports 128A-D. Foe example, enclosure system 130A may be coupled to load port 128A, enclosure system 130B may be coupled to load port 128B, enclosure system 130C may be coupled to load port 128C, and enclosure system 130D may be coupled to load port 128D. In some implementations, one or more enclosure systems 130 are coupled to the load ports 128 for transferring substrates and/or other items into and out of the processing system 100. Each of the enclosure systems 130 may seal against a respective load port 128. In some implementations, a first enclosure system 130A may be docked to a load port 128A. Once such operations are performed, the first enclosure system 130A may be undocked from the load port 128A, and then a second enclosure system 130 (e.g., a FOUP containing substrate) may be docked to the same load port 128A. In some implementations, an enclosure system 130 (e.g., enclosure system 130A) is a system for performing a calibration operation or a diagnostic operation. In some implementations, an enclosure system 130 (e.g., enclosure system 130B) is a process kit enclosure system for transferring content 110 such as process kit rings into and out of the processing system 100.

In some implementations, a load port 128 may include a front interface that forms an opening. The load port 128 may additionally include a horizontal surface for supporting an enclosure system 130. Each enclosure system 130 may have a front interface that forms a vertical opening. The front interface of the enclosure system 130 may be sized to interface with (e.g., seal to) the front interface of the load port 128 (e.g., the vertical opening of the enclosure system 130 is approximately the same size as the vertical opening of the load port 128). The enclosure system 130 may be placed on the horizontal surface of the load port 128 and the vertical opening of the enclosure system 130 aligns with the vertical opening of the load port 128. The front interface of the enclosure system 130 may interconnect with (e.g., clamp to, be secured to, be sealed to) the front interface of the load port 128. A bottom plate (e.g., base plate) of the enclosure system 130 may have features (e.g., load features, such as recesses or receptacles, that engage with load port kinematic pin features, a load port feature for pin clearance, and/or an enclosure system docking tray latch clamping feature) that engage with the horizontal surface of the load port 128. The same load ports 128 may be used for different types of enclosure systems 130.

In some implementations, the enclosure system 130B (e.g., process kit enclosure system) may include one or more items of content 110 (e.g., one or more of a process kit ring, an empty process kit ring carrier, a process kit ring disposed on a process kit ring carrier, a placement validation wafer, etc.). In some examples, the enclosure system 130B may be coupled to the FI 101 (e.g., via load port 128) to enable automated transfer of a process kit ring on a process kit ring carrier into the processing system 100 for replacement of a used process kit ring.

In some implementations, the processing system 100 may also include first vacuum ports 103a, 103b coupling the FI 101 to respective degassing chambers 104a, 104b. Second vacuum ports 105a, 105b may be coupled to respective degassing chambers 104a, 104b and disposed between the degassing chambers 104a, 104b and a transfer chamber 106 to facilitate transfer of substrates and other content 110 (e.g., process kit rings) into the transfer chamber 106. In some implementations, a processing system 100 may include and/or use one or more degassing chambers 104 and a corresponding number of vacuum ports 103, 105 (e.g., a processing system 100 includes a single degassing chamber 104, a single first vacuum port 103, and a single second vacuum port 105). The transfer chamber 106 may include a plurality of processing chambers 107 (e.g., four processing chambers 107, six processing chambers 107, etc.) disposed therearound and coupled thereto. The processing chambers 107 may be coupled to the transfer chamber 106 through respective ports 108, such as slit valves or the like. In some implementations, FI 101 may be at a higher pressure (e.g., atmospheric pressure) and the transfer chamber 106 may be at a lower pressure (e.g., vacuum). Each degassing chamber 104 (e.g., load lock, pressure chamber) may have a first door (e.g., first vacuum port 103) to seal the degassing chamber 104 from FI 101 and a second door (e.g., second vacuum port 105) to seal the degassing chamber 104 from the transfer chamber 106. Content may be transferred from the FI 101 into a degassing chamber 104 while the first door is open and the second door is closed. When the first door is to close, the pressure in the degassing chamber 104 may be reduced to match the transfer chamber 106, and when the second door is to open, the content may be transferred out of the degassing chamber 104. A local center finding (LCF) device may be used to align the content in the transfer chamber 106 (e.g., before entering a processing chamber 107, after leaving the processing chamber 107).

In some implementations, the processing chambers 107 may include or more of etch chambers, deposition chambers (including atomic layer deposition, chemical vapor deposition, physical vapor deposition, or plasma enhanced versions thereof), anneal chambers, or the like.

The factory interface 101 may include a factory interface robot 111. Factory interface robot 111 may include a robot arm, such as a selective compliance assembly robot arm (SCARA) robot. Examples of a SCARA robot include a 2 link SCARA robot, a 3 link SCARA robot, a 4 link SCARA robot, and so forth. The factory interface robot 111 may include an end effector on an end of the robot arm. The end effector may be configured to pick up and handle specific objects, such as wafers. Alternatively or additionally, the end effector may be configured to handle objects such as a calibration substrate and process kit rings (edge rings). The robot arm may have one or more links or members (e.g., wrist member, upper arm member, forearm member, etc.) that are configured to move the end effector in different orientations and to different locations.

The factory interface robot 111 is configured to transfer objects between the enclosure systems 130 (e.g., cassettes, FOUPs) and the degassing chambers 104a, 104b (or load ports). The factory interface robot 111 may be taught a fixed location relative to a load port 128 using the enclosure system 130 in implementations. The fixed location in one implementation may correspond to a center location of an enclosure system 130A placed at a particular load port 128, which may also correspond to a center location of an enclosure system 130B placed at the particular load port 128. Alternatively, the fixed location may correspond to other fixed locations within the enclosure system 130, such as a front or back of the enclosure system 130. The factory interface robot 111 may be calibrated using the enclosure system 130 in some implementations.

Transfer chamber 106 may include a transfer chamber robot 112. The transfer chamber robot 112 may include a robot arm with an end effector at an end of the robot arm. The end effector may be configured to handle particular objects, such as wafers. In some implementations, the transfer chamber robot 112 may be a SCARA robot but may have fewer links and/or fewer degrees of freedom than the factory interface robot 111 in some implementations.

A controller 109 may control various aspects of the processing system 100. The controller 109 is and/or may include a computing device such as a personal computer, a server computer, a programmable logic controller (PLC), a microcontroller, and so forth. The controller 109 may include one or more processing devices, which may include processing devices such as a microprocessor, a central processing unit, and/or the like. For example, the processing device may include a processor implementing other instruction sets or processors implementing a combination of instruction sets. In some implementations, the processing device is one or more special-purpose processing devices such as an application specific integrated circuit (ASIC), a field programmable gate array (FPGA), a digital signal processor (DSP), network processor, or the like. In some implementations, the controller 109 may include a data storage device (e.g., one or more disk drives and/or solid state drives), a main memory, a static memory, a network interface, and/or other components. In some implementations, the controller 109 executes instructions to perform any one or more of the methods or processes described herein. The instructions are stored on a non-transitory computer-readable storage medium, which include one or more of the main memory, static memory, secondary storage and/or processing device (during execution of the instructions). The controller 109 may receive signals from and sends controls to factory interface robot 111 and wafer transfer chamber robot 112 in some implementations.

According to one aspect of the disclosure, to transfer content 110 (e.g., a substrate or a process kit ring) into a processing chamber 107, the content 110 is removed from a process kit enclosure system 130B via factory interface robot 111 located in the FI 101. The factory interface robot 111 transfers the content 110 through one of the first vacuum ports 103a, 103b and into a respective degassing chamber 104a, 104b. A transfer chamber robot 112 located in the transfer chamber 106 removes the content 110 from one of the degassing chambers 104a, 104b through a second vacuum port 105a or 105b. The transfer chamber robot 112 moves the content 110 into the transfer chamber 106, where the content 110 is transferred to a processing chamber 107 through a respective port 108. After processing, the processed content 110 (e.g., a used process kit ring) is removed from the processing system 100 in reverse of any manner described herein.

The processing system 100 includes chambers, such as the FI 101 (e.g., equipment front end module, EFEM) and adjacent chambers (e.g., load port 128, enclosure system 130, SSP, degassing chamber 104 (such as a loadlock chamber), or the like) that are adjacent to the FI 101. Some or all of the chambers may be sealed. In some implementations, inert gas (e.g., one or more of nitrogen, argon, neon, helium, krypton, or xenon) may be provided into one or more of the chambers (e.g., FI 101 and/or adjacent chambers) to provide one or more inert environments. In some examples, the FI 101 is an inert EFEM that maintains the inert environment (e.g., inert EFEM minienvironment) within the FI 101 so that users do not need to enter the FI 101 (e.g., the processing system 100 is configured for no manual access within FI 101).

In some implementations, gas flow (e.g., inert gas, nitrogen) may be provided into one or more chambers (e.g., FI 101) of the processing system 100. In some implementations, the gas flow may be greater than leakage through the one or more chambers to maintain a positive pressure within the one or more chambers. In some embodiments, the inert gas within the FI 101 may be recirculated. In some implementations, a portion of the inert gas may be exhausted. In some implementations, the gas flow of non-recirculated gas into the FI 101 may be greater than the exhausted gas flow and the gas leakage to maintain a positive pressure of inert gas within FI 101. In some implementations, the FI 101 may be coupled to one or more valves and/or pumps to provide the gas flow into and out of the FI 101. A processing device (e.g., of controller 109) may control the gas flow into and out of the FI 101. In some implementations, the processing device receives sensor data from one or more sensors (e.g., oxygen sensor, moisture sensor, motion sensor, door actuation sensor, temperature sensor, pressure sensor, etc.) and determines, based on the sensor data, the flow rate of inert gas flowing into and/or out of FI 101.

The enclosure system 130 also allows for teaching, calibrating, and/or diagnosing a robot arm (e.g., of factory interface robot) without opening the sealed environment within FI 101 and adjacent chambers. The enclosure system 130 may seal to the load port 128 responsive to being docked on the load port 128. The enclosure system 130 may provide purge port access so that the interior of the enclosure system 130 can be purged prior to opening the enclosure system 130 to minimize disturbance of the inert environment within FI 101.

The processing system 100 may include an aligner system 150 having optical inspection functionality, as disclosed in more detail below. In some implementations, after the FI robot 111 retrieves content 110 (e.g., wafer) from one of the enclosure systems 130A-D, FI robot 111 can place content 110 on aligner system 150. Having detected arrival of content 110, aligner system 150 may cause an associated optical inspection system to collect defect inspection data. A data processing server may process the collected inspection data and make a determination whether to direct content 110 into transfer chamber 106 (for processing by one of processing chambers 107) or to return content 110 to the enclosure system 130.

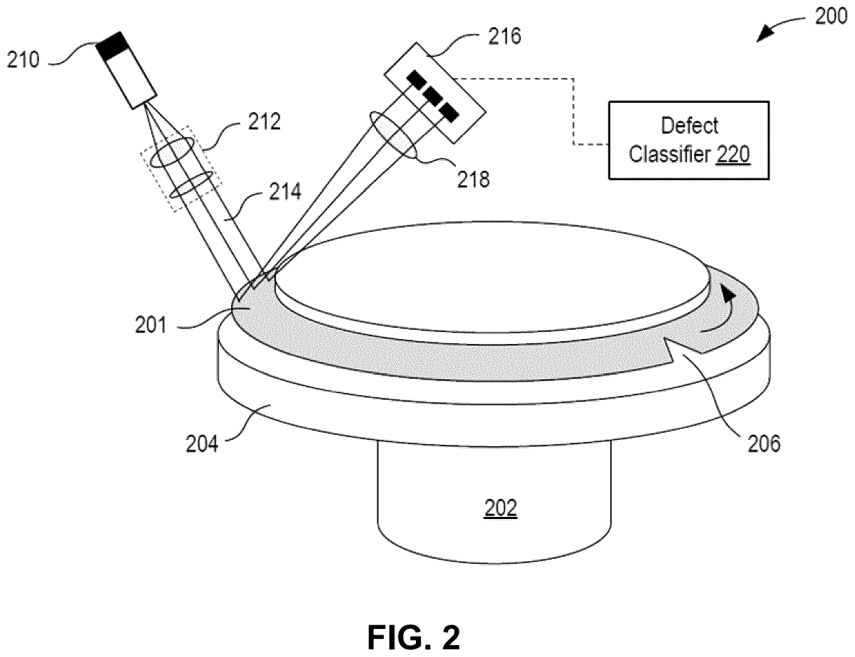

FIG. 2 illustrates a portion of an example optical inspection system 200 for detection of defects in wafers rotated by an aligner 202, according to some embodiments. In some implementations, aligner 202 can be located within an FI of a manufacturing system (e.g., FI 101 of FIG. 1). Optical inspection system 200 can also be located within the FI. In some implementations, at least a portion of the optical inspection system 200 can be located outside the FI. For example, a light detection system of the optical inspection system 200 can collect reflected (scattered) light through a window of the FI. A wafer 201 can be supported by a rotating element 204 (e.g., a pedestal, chuck, or clamp) of the aligner 202. The rotating element 204 may rotate wafer 201 with a 50-200 rpm rotation frequency. In some implementations, the rotation frequency may be below 50 rpm (e.g., 10 rpm or even lower) or above 200 rpm (e.g., 250 rpm). The aligner 202 may use the rotation of wafer 201 to identify position of one or more notches 206. The notch(es) 206 may indicate specific directions of wafer 201, such as crystallographic axes of wafer 201, orientation of patterning or any other features previously deposited or etched on wafer 201, and/or the like.

The aligner 202 may use mechanical or optical techniques to locate the notch(es) 206. Optical notch locators may deploy optical detectors not depicted in FIG. 2A. In some implementations, the location of the notch(es) 206 may be determined using the same optical inspection system 200 that is used for defect detection. The optical inspection system 200 may include one or more light sources, such as light source 210 configured to generate a beam of light that is used for illumination of wafer 201 or (as illustrated in FIG. 2A) an edge region of wafer 201. The light source 210 may be a pulsed laser, a continuous wave laser, a light-emitting diode, or any other suitable light source. The light source 210 may emit a narrowband light, a broadband light, a white light, and/or the like. Light emitted by the light source 210 may be expanded, collimated, focused, and/or the like, by illumination optics 212, which may include any number of lenses, mirrors, beam splitters, and/or the like. In some implementations, the illumination optics 212 may include masks, polarizers, and/or other optical elements to generate a polarized beam of light.

A light beam 214 generated by light source 210 and optionally conditioned by the illumination optics 212 may strike a surface of the wafer 201 and reflect (and/or scatter) towards a light detector 216, optionally passing through a set of relay optics 218. The relay optics 218 may include one or more optical elements (e.g., lenses, mirrors, waveguides, arrays of waveguides, optical fibers, etc.) to deliver (e.g., focus) the reflected/scattered light onto image sensors of light detector 216. The image sensors may include complementary metal-oxide-semiconductor (CMOS) image sensors, charge-coupled devices (CCDs), hybrid CMOS-CCD image sensors, photomultiplier tubes (e.g., an array of photocathode-based pixels), photodiodes, phototransistors, or any other suitable photon detectors. Light intensity data collected by the light detector 216 may be provided to a defect classifier 220 that determines sizes/types/concentrations/locations of various defects and imperfections in wafer 201. In some implementations, the minimum size of defects discoverable by optical inspection system 200 can be 50 μm or even lower.

In some implementations, CMOS image sensors, CCD image sensors, and/or any other images sensing elements of light detectors 216 can operate in a time delay and integration (TDI) mode. For example, if light source 210 is a pulsed light source, each pulse can correspond to a sensing frame. In the TDI mode, each sensing pixel may aggregate electrical signals (e.g., charge signals, voltage signals, etc.) generated during multiple sensing frames. As the wafer is being rotated by aligner 202, signal aggregation in the TDI mode (synchronized with wafer 201 rotation) may be performed for pixels that capture light reflected/scattered from the same regions of rotating wafer 201 (e.g., each one or several periods of wafer 201 rotation).

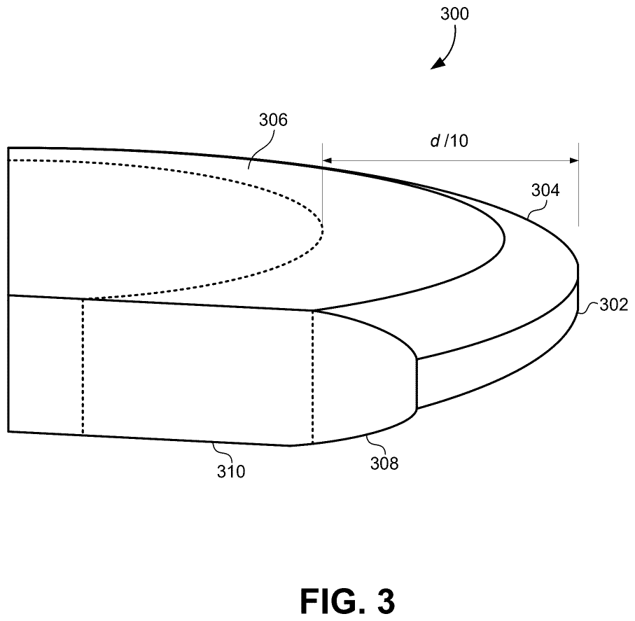

FIG. 3 illustrates a diagram of a wafer 300, according to some embodiments. The wafer may be formed from any material, including silicon, quartz, gallium arsenide, silicon carbide, gallium nitride, indium phosphide, germanium, zinc oxide, cadmium telluride, copper indium gallium selenide, organic materials, and other similar materials. The wafer 300 may be a bare wafer or may include any number of layers, films, circuits, devices, and so forth, former thereon. As described above, the wafer 300 may be between processes, such as deposition processes, etch processes, polishing processes and so forth. Specifically, the wafer 300 may be placed on the aligner system 150 illustrated in FIG. 1. While in the aligner system 150, a rotational motion may be imparted to the wafer, and the optical inspection system may be configured to collect imaging data for at least a portion of the wafer during the rotational motion.

As described in FIG. 2, the optical inspection system may be configured to collect imaging data from the entire surface of the wafer. However, some wafer types and/or some film types may yield imaging data that is particularly useful around a periphery of the wafer 300. Therefore, the optical inspection system may be configured to collect imaging data from a portion of the wafer, where that portion is along the periphery or perimeter of the wafer 300. For example, the imaging data may be collected for a portion of the wafer within a distance d/10 from an edge of the wafer, wherein d is a diameter of the wafer. This area along the perimeter of the wafer 300 may be particularly susceptible to defects, such as pitting defects, film bevel defects, edge chipping defects, stain defects, and peeling defects. Particularly, this area along the perimeter of the wafer 300 may be particularly susceptible to arcing and damage caused by arcing. Therefore, inspecting wafers along the perimeter may be particularly important in detecting defective wafers and/or processes causing defective wafers. For example, deposition processes may pause and inspect the edge of the wafers for evidence of arcing every 50 cycles, 100 cycles, 150 cycles, 200 cycles, and so forth.

In order to accurately detect signs of arcing or other defects on the edge of the wafer 300, some of the embodiments described herein may utilize an optical inspection system that is specifically configured to capture imaging data from the periphery of the wafer 300. The periphery of the wafer 300 may include a number of different zones, or sections, that may require different imaging techniques in order to accurately detect defects. For example, the outermost edge of the wafer 300 may include a zone 302 that is substantially perpendicular to the flat surface of the wafer 300 as illustrated in FIG. 3. This zone 302 may be readily viewed by a camera that is directed perpendicularly at the edge of the wafer 300. Note that the zone 300 is depicted as being flat with a substantially vertical surface in FIG. 3. However, zone 302 on some wafers may also have a rounded profile.

The wafer 300 may also include a zone 304 and a zone 308 on the top and bottom of the edge of the wafer 300, respectively. Zone 304 and a zone 308 that may be referred to as a bevel or a bevel edge of the wafer 300. This bevel area may transition from the vertical profile of zone 302 into the flat surface of the top and bottom of the wafer 300. The bevel may have a rounded profile, a slanted profile, or other profiles not specifically depicted in FIG. 3. The outer portion of the wafer 300 may also include zone 306 and zone 310 on the top and bottom of the wafer 300, respectively. These zones may be substantially flat and part of the top and bottom surfaces of the wafer 300. However, these zones may still be susceptible to arcing and other defects that may be detected by the optical inspection system.

A technical problem exists in attempting to capture images of the periphery of the wafer as illustrated in FIG. 3. Specifically, the single light source 210 illustrated in FIG. 2 can only direct the light at a single angle onto the wafer. However, the periphery of the wafer 300 includes multiple surfaces represented by the different zones illustrated in FIG. 3. Each of these different zones may have a different angle of reflection incident to a single light source. In other words, directing a light source at the edge of the wafer 300 may only reflect light directly into the imager from one of the zones at a time. Other zones will not reflect directly into the camera, resulting in darker images. These darker images may not include enough imaging data with sufficient contrast or brightness to detect a defect in the zones. For example, defects on the bevel portions of the wafer 300 in zone 304 and zone 308 are difficult to capture when the camera and and/or single light source are aimed directly at the edge portion of zone 302.

The embodiments described herein solve this technical problem by positioning a light source to direct light at a bevel of the wafer such that the light reflects off the bevel of the wafer directly into the camera. Additionally, some embodiments may provide multiple light sources, each of which are directed onto different zones of the wafer 300 such that the light reflects back into the camera. This allows the imager to capture multiple zones simultaneously with sufficient quality to detect defects along the edge of the wafer 300.

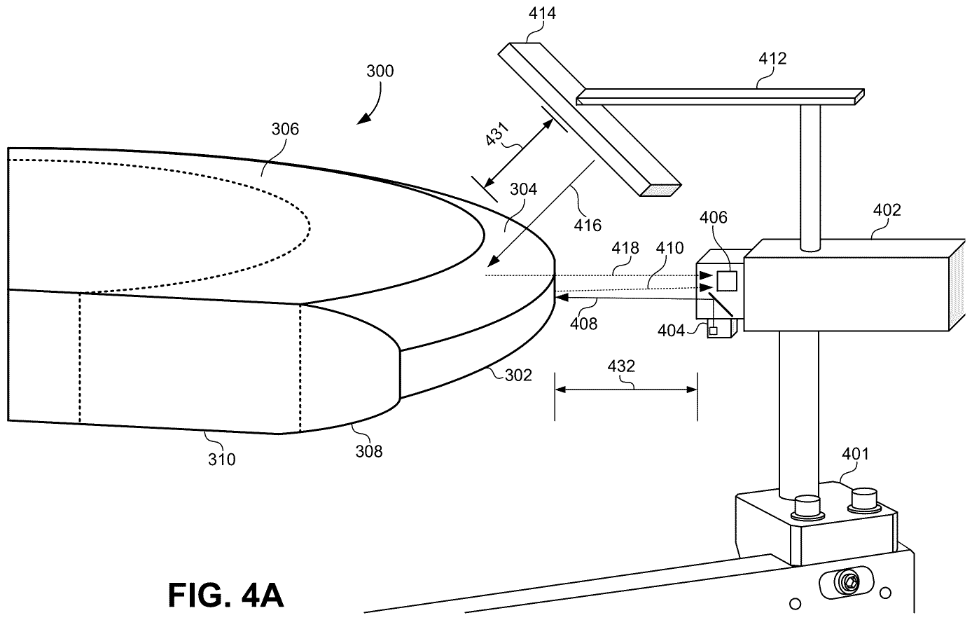

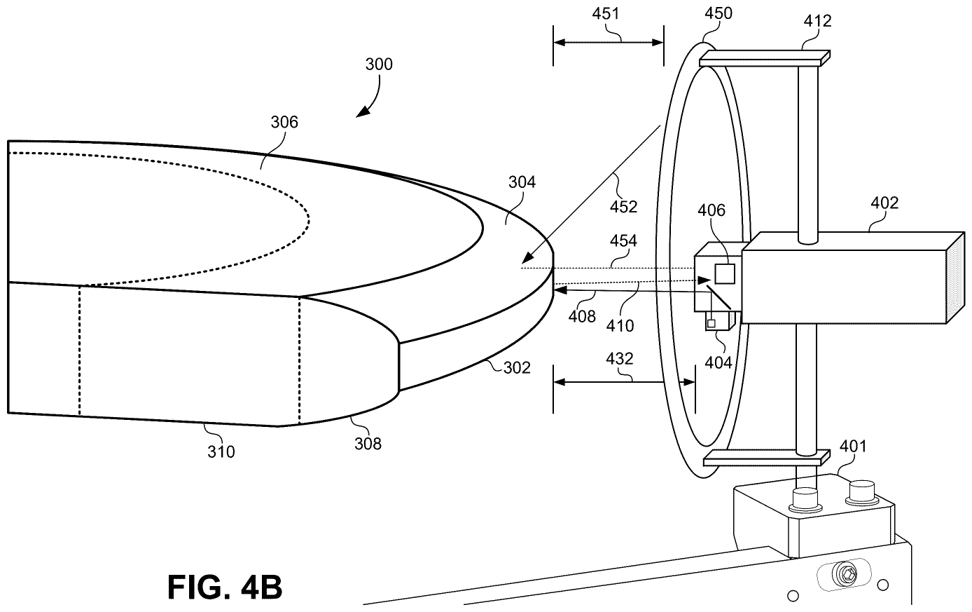

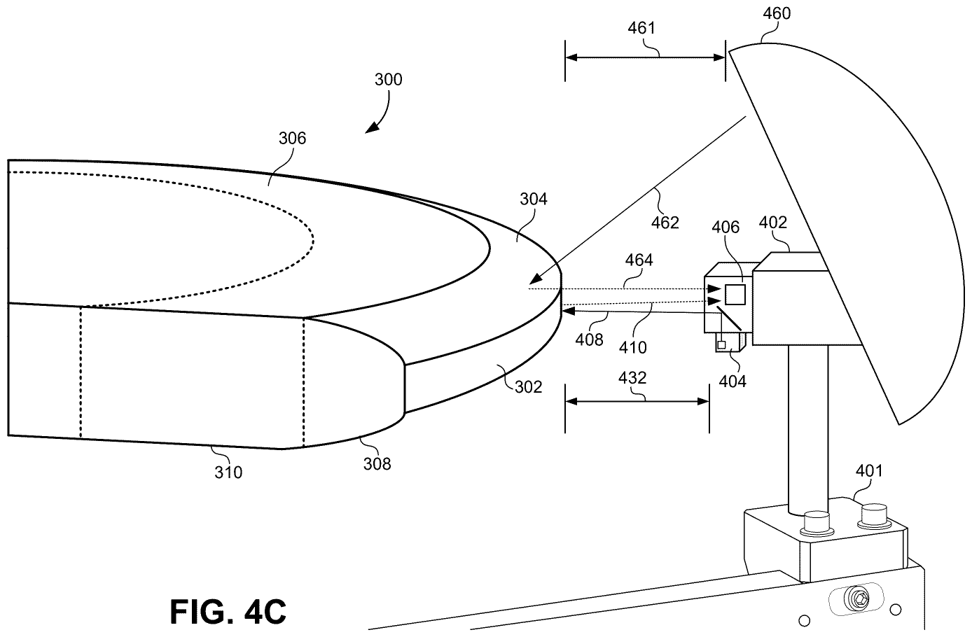

FIG. 4A illustrates a portion of an optical inspection system using an overhead light to illuminate the bevel of the wafer, according to some embodiments. The optical inspection system may include a camera 402. The camera may comprise a single integrated unit as illustrated in FIG. 4A. For example, the camera 402 may include one or more image sensors 406, such as CMOS image sensors, CCD sensors, photomultiplier tubes, photodiodes, phototransistors, or any other suitable photon detector. The camera may also include one or more processors configured to process the light received by one or more image sensors 406 and convert the light signals into a digital image. In some environments, the camera 402 need not be a single integrated unit. Instead, lenses, fiberoptics, and/or other means of directing light may be placed at the edge of the bevel 300. These light directing devices may then carry the received light to the one or more image sensors 406 in a location that is away from the wafer 300 or the FI. Therefore, the term “camera” may refer to any combination of light directing devices, image sensors, and/or processing units.

In this configuration, the camera 402 may be directed or aimed at zone 302 on the wafer 300. In other words, the camera 402 may be directed along an axis that is perpendicular to the edge of the wafer in zone 302. In order to illuminate this zone, a light source 404 may be configured to direct light perpendicularly at the edge of the wafer 300. In one example, the light source 400 may be oriented upwards and light 408 emitted from the light source 404 may be reflected off of a 45° mirror to be coaxial with the view axis of the camera 402. Therefore, this light may be aimed directly at the perpendicular edge of the wafer 300. The reflected light 410 from the perpendicular edge of the wafer 300 may also be coaxial and received directly by the one or more image sensors 406. This has the effect of clearly and distinctly illuminating zone 302 of the wafer 300.

As described above, the light 408 emitted from the light source 404 may not be aimed at a perpendicular surface in zone 304 and/or zone 308. Instead, the light 408 emitted from the light source 404 will be reflected off at an angle when incident on the zones. Therefore, the amount of light scattered or reflected from these surfaces that is captured by the one or more image sensors 406 may have a much lower intensity. Instead of being reflected back towards the camera 402, light from the light source 404 that is incident upon zone 304 may be reflected at a different angle (e.g., towards the top of the chamber). This results in a much darker image of zone 304 with much lower contrast, making it difficult to accurately identify defects based on the image details.

To overcome this challenge, some embodiments may also include a light source 414 that is positioned to direct light at a bevel of the wafer 300. For example, the light source 414 may be angled and/or positioned such that light 416 from the light source 414 is aimed at the bevel profile of zone 304 or zone 308. Note that the direction of the light 416 need not be perpendicular to the surface of the bevel. Instead, the angle of incidence of the light 416 on the bevel surface should be such that the angle of reflection directs the light 418 directly into the one or more image sensors 406 of the camera 402. This angle of the light source 414 may depend on the profile of the bevel of the wafer 300. This angle may be readily calculated based on the position and angle of the light source 414 and the average tangential slope of the bevel. Alternatively, the light source 414 may be positioned experimentally by adjusting the angle of the light source 414 such that the brightness of the resulting image is maximized or optimized for detecting defects.

In the example of FIG. 4A, the light source 414 is only illustrated to be above the wafer 300 and configured to optimize images captured of zone 304 on top of the wafer 300. However, other embodiments may include additional light sources that are positioned to optimize images captured of other zones. For example, a light source similar in configuration to light source 414 may be placed below the camera 402 and configured to optimize an image of zone 308. This additional light source has been omitted from FIG. 4A for the sake of clarity. This additional light source allows a single image to capture high quality views of zone 302, zone 304, and zone 308 simultaneously by lighting each of the zones individually.

Other embodiments may include more than three light sources, depending on the nature of the bevel and the edge profile of the wafer 300. For example, other wafers may include angled portions of the edge profile rather than a continuous bevel. The optical inspection system may consequently include multiple light sources, each of which are positioned and/or angled to direct light onto individual zones of the edge of the wafer such that the reflected light from each of the sections is aimed into the one or more image sensors 406 of the camera 402. Additional lighting configurations are shown in the subsequent figures. Different configurations may therefore use different numbers of light sources, each of which may be directed at a different profile or angled portion of the edge of the wafer 300, and each of which may be configured to direct reflected light from those profiles back into the camera 402. These light sources may be added or removed interchangeably without limitation. For example, the light source 414 above the wafer 300 and a similar light source positioned below the wafer 300 may be used without the coaxial light from the light source 404. Multiple light sources present in the system that may also be dynamically turned on/off at the time of use. For example, an image may be taken using one subset of light sources, and a second image may then be taken using another subset of light sources.

In some cases, the light source 414 may be referred to as a “first” light source, and the light source 404 may be referred to as a “second” light source. Other light sources may be referred to as “third,” “fourth,” and so forth. The terms first, second, etc., are only used to distinguish one light source from another light source. These terms are not meant to imply order, importance, or any other characteristic of the light sources.

The configuration of FIG. 4A illustrates the light source 414 being mounted to a fixture 412 that is coupled to the camera 402 and/or a camera mount 401. This ensures that the angle and position of the light source 414 is fixed or held steady relative to the angle and position of the camera 402. However, other embodiments may mount the light source 414 and other light sources on fixtures that are separate and unattached from the camera 402 and/or the camera mount 401. For example, the light source 414 may be mounted to portions of the aligner system or other surfaces in the factory interface illustrated in FIG. 1.

The light source 414 may be configured to have a higher intensity or brightness than the light source 404. For example, the continuous curvature or bevel of zone 304 may result in less of the light 418 be reflected directly into the one or more imager sensors 406. Additionally, the surface of zone 304 is farther from the camera 402 than the surface of zone 302. Therefore, the brightness or intensity of the light source 414 may be increased to compensate for these differences. In some embodiments, the brightness or intensity of the light source 414 may be at least 10% brighter than the brightness or intensity of the light source 404. In other embodiments, the light source 414 may be between 10% brighter and 20% brighter, between 20% brighter and 30% brighter, between 30% brighter and 40% brighter, between 40% and 50% brighter, between 50% and 60% brighter, between 60% and 75% brighter, between 75% and 100% brighter, and/or greater than 100% brighter than the light source 404. The relative brightness of the light source 414 may also be any combination of intervals described above (e.g., between 20% and 70% brighter). The relative brightness may also be any single value contained within intervals described above (e.g., about 50% brighter). The brightness or intensity of the light source 414 may be dynamically adjustable at the time of use. For example, the brightness or intensity of the light source 414 may be increased when the rotational motion is imparted to the wafer 300 depending on the size of the wafer, the profile characteristics of zone 304, and so forth.

In addition to a difference in brightness or intensity, the light sources may also be positioned at different distances from the wafer 300. Generally, space constraints within the factory interface may limit the distance from the wafer and the position of the camera 402. Therefore, the camera 402, the light source 404 and the light source 414 may all be within 150 mm of the edge of the wafer 300. For example, the distance 432 between the edge of the wafer 300 and the camera 402 may be between 5 mm and 10 mm, between 10 mm and 20 mm, between 20 mm and 30 mm, between 30 mm and 40 mm, between 40 mm and 50 mm, between 50 mm and 75 mm, between 75 mm and 100 mm, between 100 mm and 125 mm, and/or between 125 mm and 150 mm. The distance 432 may also be represented by any combination of the ranges described above (e.g., between 20 mm and 100 mm). The distance 432 may also be represented by any single value within the ranges described above (e.g., 65 mm).

Similarly, the distance 431 between the light source 414 and the edge of the wafer in zone 304 may be between 5 mm and 10 mm, between 10 mm and 20 mm, between 20 mm and 30 mm, between 30 mm and 40 mm, between 40 mm and 50 mm, between 50 mm and 75 mm, between 75 mm and 100 mm, between 100 mm and 125 mm, and/or between 125 mm and 150 mm. The distance 432 may also be represented by any combination of the ranges described above (e.g., between 10 mm and 50 mm). The distance 432 may also be represented by any single value within the ranges described above (e.g., 35 mm).

These distances may also be characterized relative to each other. For example, the distance 431 may be between 0.1 and 0.95 of the distance 432 (e.g., between 10% and 95%). More specifically, the distance 431 may be between 0.1 and 0.2, between 0.2 and 0.3, between 0.3 and 0.4, between 0.4 and 0.5, between 0.5 and 0.6, between 0.6 and 0.7, between 0.7 and 0.8, between 0.8 and 0.9, and/or between 0.9 and 1.0 of the distance 432.

Like the intensity of the light source 414, the position of the light source 414 may be mechanically adjustable by the controller or processing system. For example, the fixture 412 may include a motor or other mechanical adjustment components that can be automatically or manually adjusted to reposition the angle and/or position of the light source 414. The distance 431 may be adjusted as images are captured in order to capture images having the highest contrast or quality. A computer system or controller may automatically adjust the angle and/or position to detect the maximum intensity of light received from the target portion of the wafer 300. For example, images may be captured as the position and/or angle are adjusted, a maximum intensity of the reflected light may be detected, and the corresponding position/angle may be used for subsequent images.

The light source 414 and/or the light source 104 may be configured to emit any wavelength of light. For example, these light sources may use white light. However, it has been discovered that using light with shorter wavelengths may be better at detecting small defects. Therefore, some embodiments may use a wavelength of light being characterized by a blue color (e.g., about 450 nm to about 495 nm. Other embodiments may use shorter wavelengths, such as between about 380 nm and about 450 nm.

FIG. 4B illustrates a portion of an optical inspection system using a ring light to illuminate the bevel of the wafer, according to some embodiments. Instead of using one or more lights positioned above or below the wafer 300 as in FIG. 4A, some embodiments may use a ring light 450 as a light source that projects light above and below the wafer 300 simultaneously. Although shown as being oriented perpendicularly to the wafer 300 in FIG. 4B, some embodiments may tilt the ring light 450 to better illuminate either the top bevel in zone 304 or the bottom bevel of zone 308. Some embodiments may use a ring light that is bent at the middle to “wrap around” the edge profile of the wafer 300. This may simultaneously illuminate both the top and bottom bevel of the wafer 300.

The ring light 450 may operate using the same features described above for the light source 414 of FIG. 4A. For example, the ring light 450 may be dynamically adjustable in position, angle, and/or intensity at the time of use and controller by the controller or processing unit. The ring light 450 may be positioned such that light 452 that is projected onto the bevel of zone 304 such that the angle of reflection incident on the bevel directs the reflected light 454 into the camera 402. The intensity of the ring light 450 may be adjustable to be brighter than the intensity of the light from the light source 404. The distance 451 between the ring light 450 and the wafer 300 may be shorter than the distance 432 between the light source 404 and the wafer 300. The ring light 450 may emit white, blue, or other colors of light, and so forth.

FIG. 4C illustrates a portion of an optical inspection system using a dome light 460 to illuminate the bevel of the wafer, according to some embodiments. The dome light 460 may be positioned behind the camera 402 as depicted. The dome light 460 may reflect light off the curvature of the dome profile to direct light around the bevel of the wafer 300. The dome light 460 may be mechanically adjustable before or during use to adjust an angle at which the dome light 460 is oriented relative to the wafer 300. In this example, the dome light 460 is angled downwards towards the top portion of the bevel of zone 304. However, the dome light 460 may also be adjusted such that it is angled upwards towards the bottom of the bevel, angled directly at the edge of zone 302 of the wafer, and/or angled at any other orientation.

In this example, the distance 461 between the dome light 460 and the wafer 300 may be greater than the distance 432 between the light source 404 and the wafer 300. This relative distance may be due to the position of the dome light 460 behind the camera 402. Other embodiments may change the position of the dome light 460 such that the distance 461 is less than the distance 432. Alternatively, the intensity or brightness of the dome light 460 may be increased to compensate for the distance 461 being greater than the distance 432.

The dome light 460 may operate using the same features described above for the light source 414 of FIG. 4A. For example, the dome light 460 may be dynamically adjustable in position, angle, and/or intensity at the time of use and controller by the controller or processing unit. The dome light 460 may be positioned such that light 462 that is projected onto the bevel of zone 304 such that the angle of reflection incident on the bevel directs the reflected light 464 into the camera 402. The intensity of the dome light 460 may be adjustable to be brighter than the intensity of the light from the light source 404. The dome light 460 may emit white, blue, or other colors of light, and so forth.

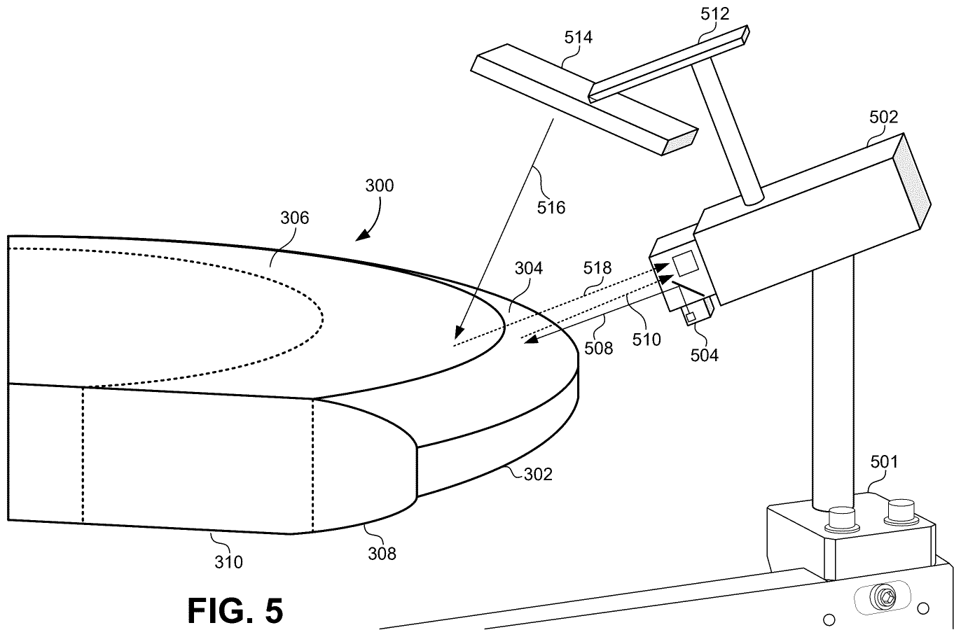

FIG. 5 illustrates how the position or orientation of the optical inspection system itself may be changed to capture different zones on the wafer 300, according to some embodiments. This configuration is similar to the configuration of FIG. 4A except that the camera 502 is directed towards the bevel of zone 304. More specifically, the light source 504 is configured to direct light 508 directly at the bevel of zone 304 such that the angle of reflection directs the reflected light 510 back into the camera 500 and to. The light source 504 may still be considered a coaxial light source for the camera 502.

A light source 514 may be positioned or angled on the mount 512 such that the light 516 is directed towards the flat surface of zone 306 With an angle of reflection that directs the reflected light 518 back into the camera 502. Note that FIG. 5 is not drawn to scale, and the position of the light source 514 may be different to create this reflective angle. The light source 504, camera 502, and the light source 514 may operate using any of the feature description provided above for the system of FIG. 4A. Additionally, the light source 504 may be replaced with the ring light of FIG. 4B, the dome light of FIG. 4C, and/or any other type of light.

By changing the position of the camera 502, different zones may be imaged simultaneously. For example, instead of capturing images of zone 302 and zone 304, this configuration captures images of zone 304 and zone 306. Alternatively, the position and orientation of the optical inspection system may be changed to instead simultaneously image zone 380 and zone 310 by directing the camera 502 towards the bottom side of the wafer 300. In some embodiments, the position and orientation of the optical inspection system may be changed dynamically during use. For example, as the wafer spins, a first set of images may be captured of zone 306 and zone 304, then a second set of images may be captured of zone 304 and zone 302, and so forth. By rotating the camera around the edge of the wafer 300, multiple zones may be imaged effectively.

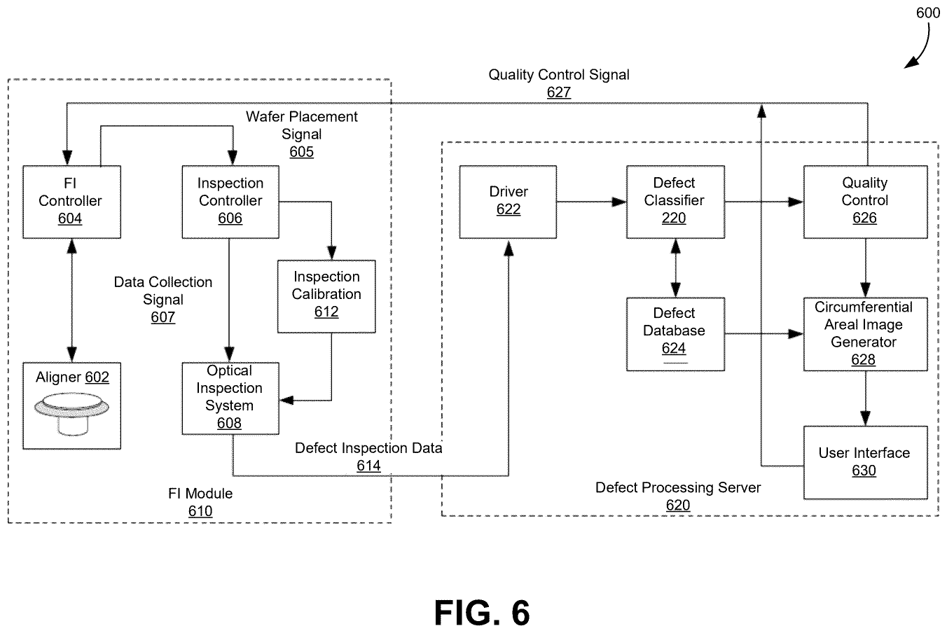

FIG. 6 illustrates an example architecture of a defect detection system 600, operating in accordance with some implementations of the present disclosure. The defect detection system 600 may include an FI module 610 and a data processing server 620. The FI module 610 may include an aligner 602 (e.g., aligner 202 of FIG. 2) configured to impart rotation to a wafer, e.g., as part of the alignment process during wafer preprocessing. Operations of the aligner 602 may be controlled by an FI controller 604. The FI controller 604 may also control various operations of other FI tools and components, such as opening one of the load ports 128A-D, loading (using the FI robot 111) a wafer (e.g., content 110) from the respective enclosure system 130 A-D, transferring the wafer from the enclosure system to FI 101, closing the load port, unsealing one of vacuum ports 103a, 103b, transferring the wafer into one of the degassing (load lock) chambers 104a, 104b, sealing the vacuum ports 103a, 103b, and or the like.

In some implementations, once the FI robot 111 has placed a wafer on aligner 602, the FI controller 604 can output a wafer placement signal 605 informing an inspection controller 606 that the wafer is ready for defect inspection. The inspection controller 606 may then generate a data collection signal 607 to an optical inspection system 608. A data collection signal 607 may cause the light source(s) and the light detector of the optical inspection system 608 to turn on and begin collection of light reflected/scattered from the wafer. Light collected by the optical inspection system 608 may be digitized, denoised, authenticated, compressed, and/or otherwise preprocessed, and output—as defect inspection data 614—to the data processing server 620.

The defect inspection data 614 may be received by a driver 622 that converts the received data into a format recognizable by a defect classifier 220. Conversion of the received data can include decompressing the data, rescaling the data, reformatting the data, tokenizing the data, and/or the like. In some implementations, the driver 622 may handle reformatting the defect inspection data into one of a plurality of formats. For example, the defect classifier 220 can deploy different models (e.g., machine learning models) for different wafer types, with different models operating on defect inspection data 614 of different formats, images resolutions, and/or the like.

The defect classifier 220 may identify (e.g., from a metadata provided by inspection controller 606) a type of a wafer undergoing inspection, such as a bare wafer, wafer with one or more deposited films, patterned wafer, and/or the like. The defect classifier 220 may select a model trained to detect defects in wafers of the identified type. The selected model can process the defect inspection data 614 and identify classes of defects present in the inspected area of the wafer (e.g., the edge region of the wafer) and the number (or density) of such defects. The defect classifier 220 may communicate with a defect database 624 that stores representative images of various kinds of defects. In some implementations, the stored images of defects may have been previously used to train various models of the defect classifier 220. In some implementations, images of new defects identified in the inspected wafers may be used to update the defect database 624.

The output of the defect classifier 220 may be used by a quality control module 626 to determine a suitability of the wafer for one or more processing operations. For example, a quality score may be computed for the wafer that is based on a number and classes of detected defects. Defects may include cracks, chipped areas, pits/holes, particle defects, contaminated areas, deformations, flaking/peeling, and/or any other types of imperfections and/or deviations from wafer specifications. A quality score may be computed in any suitable way, e.g., with weights being assigned to different classes of defects and to different numbers/densities of those defects. If the computed quality score is at or above a certain empirically determined threshold (which can be dependent on the specific wafer type), the wafer can be determined to be suitable for a subsequent downstream processing. If the computed quality score is at or below the empirically determined threshold, the wafer may be prevented from undergoing downstream processing. In some instances, such wafers may be directed for remedial processing (e.g., removal of deposited films, re-application of the films, edge polishing, etc.). In other instances, wafers with quality scores below a minimum acceptable threshold may be discarded. A quality control signal 627 may be communicated to the FI controller 604 directing the FI controller 604 to implement one of these actions in relation to the wafer currently being inspected.

In some implementations, a circumferential/areal image generator 628 may use the collected images of various regions of the wafer to generate one or more circumferential (e.g., for edge inspections) images or one or more areal (e.g., for line scan inspections) images of the wafer. The circumferential/areal images can be provided to a user, e.g., an operator of the processing line, via a user interface 630, which may be a computer screen or any other suitable device from which the images can be perceived by the user. In some instances, the user may review the determination made by the quality control module 626 and change the quality control signal 627 with the instructions to the FI controller 604 about further processing (or lack thereof) of the wafer.

In some implementations, the FI module 610 may deploy an inspection calibration module 612 that performs periodic calibration of the optical inspection system 608. For example, the inspection calibration module 612 may have access to one or more calibration wafers with known classes, numbers, and locations of defects. Calibration wafers may be used to verify and/or adjust intensity, direction, focus, polarization, pulse rate, and/or other characteristics of the light sources as well as shutter speed, positioning, focus, image acquisition rate of the camera.

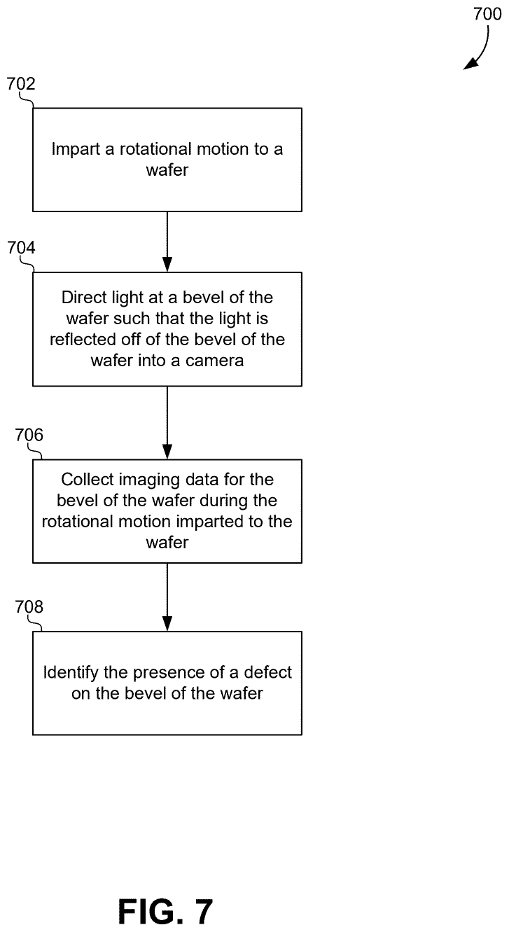

FIG. 7 illustrates a flowchart of a method 700 for detecting defects around the perimeter of wafers, according to some embodiments. In some implementations, method 700 may be performed using systems and components shown in any of the preceding figures or any combination thereof. In some implementations, method 700 may be performed using various processing devices, e.g., the FI controller, the inspection controller, and/or a data processing server. For example, the processing device(s) used to perform the method 700 may include one or more central processing units (CPUs), processors microprocessors, DSPs, ASICs, finite-state machines, FPGAs, and so on, coupled to one or more memory devices (e.g., a random-access memory, a read-only memory, a flash memory, a static memory, and so on). The one or more memory devices may store instructions that cause the processor(s) to perform the operations described herein. The method 700 may be performed on a wafer fetched (e.g., by the FI robot 111 of the FI 101 of FIG. 1) from a wafer carrier (e.g., one of the enclosure systems 130A-D).

The method may include imparting a rotational motion to a wafer (702). The rotational motion may be applied using the aligner described above. The remainder of the process may take place during, after, and/or before the aligner locates a notch or other positional indicator in the wafer. Alternatively, the rotational motion may be applied using any other pedestal or wafer support configured to rotate the wafer around a center axis.

The method may also include directing light at a bevel of the wafer such that the light is reflected off of the bevel of the wafer into a camera (704). For example, the light may be provided by the light source, such as the ring light, the dome light, lights positioned above/below the substrate, and any other configuration. The light may be directed towards the bevel such that the angle of reflection (equal to the angle of incidence) off the bevel is directed into the camera lens or other camera receptacle (e.g., a fiber-optic sensor). The light source may be one of a number of light sources, each of which may be positioned to cause light to be reflected off a different portion of the edge of the wafer into the camera. For example, this light source may be a first light source aimed at the bevel, while a second light source may be aimed at the edge of the wafer, with other light sources optionally aimed at other areas of the wafer.

The method may additionally include collecting imaging data for the bevel of the wafer (706). The imaging data may be collected by a camera and processed by a processor. The imaging data may be collected during the rotational motion imparted to the wafer by the aligner device or another rotational platform. The imaging data may include a view of the edge of the wafer, the top bevel, the bottom bevel, the top surface, the bottom surface, and/or any combination of these different zones. For example, the imaging data may include images of two or more portions of the edge of the wafer simultaneously, each of which may be illuminated by individual corresponding light sources.

The method may further include identifying the presence of a defect on the bevel of the wafer (708). For example, identifying the presence of the one or more defects in the wafer may be performed concurrently with the aligner device identifying the position of the reference feature (e.g., within several seconds that the wafer is being rotated by the aligner). The defects identified may include one or more of a chipping defect, a pitting defect, a film delamination defect, a bevel-edge defect, or a staining defect. Depending on the determined quality, method 700 may optionally select additional actions to be executed. If the quality of the wafer is at or above a threshold quality, the wafer can be determined to be suitable for further processing, and method may continue with directing the wafer for processing in a processing chamber. If the quality of the wafer below a threshold quality, the wafer can be determined to be unsuitable for further processing, and method may prevent the wafer from entering the processing chamber. In some instances, e.g., when the wafer is not suitable for further processing but is not irreversibly impaired, method may continue with directing the wafer for a defect-mitigation processing. Such defect-mitigation processing can include additional polishing, drying, cleaning, application of solvents, removal of improperly deposited films, and/or the like.

Each of the methods described herein may be implemented by a computer system or controller. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

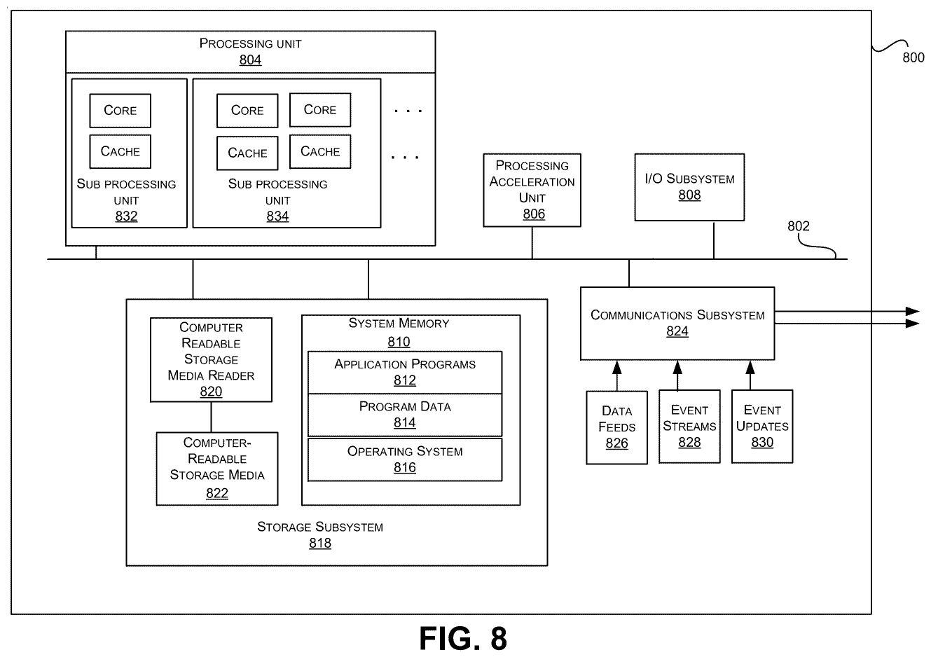

FIG. 8 illustrates an exemplary computer system 800, in which various embodiments may be implemented. The system 800 may be used to implement any of the computer systems described above. As shown in the figure, computer system 800 includes a processing unit 804 that communicates with a number of peripheral subsystems via a bus subsystem 802. These peripheral subsystems may include a processing acceleration unit 806, an I/O subsystem 808, a storage subsystem 818 and a communications subsystem 824. Storage subsystem 818 includes tangible computer-readable storage media 822 and a system memory 810.

Bus subsystem 802 provides a mechanism for letting the various components and subsystems of computer system 800 communicate with each other as intended. Although bus subsystem 802 is shown schematically as a single bus, alternative embodiments of the bus subsystem may utilize multiple buses. Bus subsystem 802 may be any of several types of bus structures including a memory bus or memory controller, a peripheral bus, and a local bus using any of a variety of bus architectures. For example, such architectures may include an Industry Standard Architecture (ISA) bus, EtherCAT, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 804, which can be implemented as one or more integrated circuits (e.g., a conventional microprocessor or microcontroller), controls the operation of computer system 800. One or more processors may be included in processing unit 804. These processors may include single core or multicore processors. In certain embodiments, processing unit 804 may be implemented as one or more independent processing units 832 and/or 834 with single or multicore processors included in each processing unit. In other embodiments, processing unit 804 may also be implemented as a quad-core processing unit formed by integrating two dual-core processors into a single chip.

In various embodiments, processing unit 804 can execute a variety of programs in response to program code and can maintain multiple concurrently executing programs or processes. At any given time, some or all of the program code to be executed can be resident in processor(s) 804 and/or in storage subsystem 818. Through suitable programming, processor(s) 804 can provide various functionalities described above. Computer system 800 may additionally include a processing acceleration unit 806, which can include a digital signal processor (DSP), a special-purpose processor, and/or the like.

I/O subsystem 808 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may also include, without limitation, three dimensional (3D) mice, joysticks or pointing sticks, graphic tablets, and audio/visual devices such as speakers, digital cameras, webcams, image scanners, fingerprint scanners, barcode reader 3D scanners, 3D printers, laser rangefinders, and so forth.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device’ is intended to include all possible types of devices and mechanisms for outputting information from computer system 800 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 800 may comprise a storage subsystem 818 that comprises software elements, shown as being currently located within a system memory 810. System memory 810 may store program instructions that are loadable and executable on processing unit 804, as well as data generated during the execution of these programs.

Depending on the configuration and type of computer system 800, system memory 810 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 804. In some implementations, system memory 810 may include multiple different types of memory, such as static random access memory (SRAM) or dynamic random access memory (DRAM). In some implementations, a basic input/output system (BIOS), containing the basic routines that help to transfer information between elements within computer system 800, such as during start-up, may typically be stored in the ROM. By way of example, and not limitation, system memory 810 also illustrates application programs 812, which may include client applications, Web browsers, mid-tier applications, relational database management systems (RDBMS), etc., program data 814, and an operating system 816.

Storage subsystem 818 may also provide a tangible computer-readable storage medium for storing the basic programming and data constructs that provide the functionality of some embodiments. Software (programs, code modules, instructions) that when executed by a processor provide the functionality described above may be stored in storage subsystem 818. These software modules or instructions may be executed by processing unit 804. Storage subsystem 818 may also provide a repository for storing data used in accordance with some embodiments.

Storage subsystem 800 may also include a computer-readable storage media reader 820 that can further be connected to computer-readable storage media 822. Together and, optionally, in combination with system memory 810, computer-readable storage media 822 may comprehensively represent remote, local, fixed, and/or removable storage devices plus storage media for temporarily and/or more permanently containing, storing, transmitting, and retrieving computer-readable information.

Computer-readable storage media 822 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information, and which can be accessed by computing system 800.

By way of example, computer-readable storage media 822 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 822 may include, but is not limited to, flash memory cards, universal serial bus (USB) flash drives, secure digital (SD) cards, DVD disks, digital video tape, and the like. Computer-readable storage media 822 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 800.

Communications subsystem 824 provides an interface to other computer systems and networks. Communications subsystem 824 serves as an interface for receiving data from and transmitting data to other systems from computer system 800. For example, communications subsystem 824 may enable computer system 800 to connect to one or more devices via the Internet. In some embodiments communications subsystem 824 can include radio frequency (RF) transceiver components for accessing wireless voice and/or data networks (e.g., using cellular telephone technology, advanced data network technology, WiFi (IEEE 802.11 family standards, or other mobile communication technologies, or any combination thereof), global positioning system (GPS) receiver components, and/or other components. In some embodiments communications subsystem 824 can provide wired network connectivity (e.g., Ethernet) in addition to or instead of a wireless interface.

Additionally, communications subsystem 824 may also be configured to receive data in the form of continuous data streams, which may include event streams 828 of real-time events and/or event updates 830, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 824 may also be configured to output the structured and/or unstructured data feeds 826, event streams 828, event updates 830, and the like to one or more databases that may be in communication with one or more streaming data source computers coupled to computer system 800.

Computer system 800 can be one of various types, including a handheld portable device, a wearable device, a PC, a workstation, a mainframe, a server rack, or any other data processing system.

Due to the ever-changing nature of computers and networks, the description of computer system 800 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification. For example, these terms may represent values within 10% of a stated value.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides example embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A semiconductor manufacturing system comprising:
an aligner configured to:
impart a rotational motion to a wafer; and
identify, using the rotational motion of the wafer, a position of a reference feature of the wafer; and
an optical inspection system configured to collect, during the rotational motion imparted by the aligner to the wafer, imaging data for a portion of the wafer, wherein the optical inspection system comprises:
a camera;
a first light source positioned to direct light at a bevel of the wafer; and
a second light source positioned to direct light perpendicularly at an edge of the wafer.

2. The semiconductor manufacturing system of claim 1, wherein the first light source is closer to the portion of the wafer than the second light source.

3. The semiconductor manufacturing system of claim 1, wherein the first light source is at least 10% brighter than the second light source.

4. The semiconductor manufacturing system of claim 1, further comprising:
a processing device programmed to identify, using the imaging data, a defect in the wafer.

5. The semiconductor manufacturing system of claim 1, wherein the aligner and the optical inspection system are located in a factory interface coupled to at least one of a load lock chamber, a transfer chamber, or a processing chamber.

6. The semiconductor manufacturing system of claim 1, wherein the rotational motion of the wafer occurs with frequency between 30 rpm and 250 rpm.

7. The semiconductor manufacturing system of claim 1, wherein the imaging data is collected for the portion of the wafer located within a distance d/10 from an edge of the wafer, wherein d is a diameter of the wafer.

8. The semiconductor manufacturing system of claim 1, further comprising a deposition chamber and a transfer robot, wherein the transfer robot is configured to move the wafer from the aligner to the deposition chamber after capturing the imaging data.

9. The semiconductor manufacturing system of claim 1, wherein the camera, the first light source, and the second light source are positioned between about 5 mm and about mm from the wafer.

10. An optical inspection system comprising:
a pedestal configured to impart a rotational motion to a wafer;
a camera configured to collect, during the rotational motion of the wafer, imaging data for at least a portion of the wafer; and
a first light source positioned to direct light at a bevel of the wafer such that the light reflects off the bevel of the wafer into the camera.

11. The optical inspection system of claim 10, further comprising:
a processing device programmed to identify, using the imaging data, one or more defects in the bevel of the wafer.

12. The optical inspection system of claim 10, further comprising:
a second light source positioned to direct light perpendicularly at an edge of the wafer, wherein the second light source is separate and distinct from the first light source.

13. The optical inspection system of claim 10, further comprising:
a second light source, wherein:
the first light source is positioned to direct light at a first portion of the bevel of the wafer; and
the second light source is positioned to direct light at a second portion of the bevel of the wafer.

14. The optical inspection system of claim 10, wherein the first light source is configured to emit light having a wavelength characterized by a blue color.

15. The optical inspection system of claim 10, wherein the first light source comprises a ring light around the camera.

16. The optical inspection system of claim 10, wherein the first light source comprises a dome light.

17. The optical inspection system of claim 10, wherein the first light source is positioned above a camera to capture the imaging data depicting a top portion of the bevel of the wafer.

18. A method comprising:
imparting a rotational motion to a wafer;
directing light at a bevel of the wafer such that the light is reflected off of the bevel of the wafer into a camera;
collecting, using the camera, imaging data for the bevel of the wafer, wherein the imaging data is collected during the rotational motion imparted to the wafer; and
identifying, using the imaging data, a presence of a defect on the bevel of the wafer.

19. The method of claim 18, wherein the defect comprises a chipping defect, a pitting defect, a film delamination defect, a bevel-edge defect, or a staining defect.

20. The method of claim 18, further comprising adjusting a brightness of the light to adjust a quality of the imaging data.
